(19) United States
(12) Patent Application Publication
(10) Pub. No.: US 2012/0009777 A1
(43) Pub. Date: Jan. 12, 2012

(54) UBM Etching Methods

(75) Inventors: Chung-Shi Liu, Shin-Chu (TW); Hung-Jui Kuo, Hsin-Chu (TW); Meng-Wei Chou, Zhubei City (TW)

(73) Assignee: Taiwan Semiconductor Manufacturing Company, Ltd., Hsin-Chu (TW)

(21) Appl. No.: 12/832,005

(22) Filed: Jul. 7, 2010

(51) Int. Cl. H01L 21/768

(52) U.S. Cl. 438/614; 438/612; 257/E21.59; 257/E21.589

(57) ABSTRACT

A method of forming a device includes forming an under-bump metallurgy (UBM) layer including a barrier layer and a seed layer over the barrier layer; and forming a mask over the UBM layer. The mask covers a first portion of the UBM layer, and a second portion of the UBM layer is exposed through an opening in the mask. The first portion of the UBM layer includes a barrier layer portion and a seed layer portion. A metal bump is formed in the opening and on the second portion of the UBM layer. The mask is then removed. A wet etch is performed to remove the seed layer portion. A dry etch is performed to remove the barrier layer portion.

### TECHNICAL FIELD

This disclosure relates generally to integrated circuits, and more particularly to the methods of forming metal bumps.

### BACKGROUND

In the formation of a semiconductor wafer, integrated circuit devices such as transistors are first formed at the surface of a semiconductor substrate. Interconnect structures are then formed over the integrated circuit devices. Metal bumps are formed on the surface of the semiconductor chip, so that the integrated circuit devices can be accessed.

FIGS. 1 and 2 illustrate the cross-sectional views of intermediate stages in the manufacturing of a metal bump. Referring to FIG. 1, under-bump metallurgy (UBM) layers 104 are formed over and contacting metal pad 102. UBM layers 104 include titanium layer 106, and copper seed layer 108 over titanium layer 106. Metal bump 110 is formed on UBM layers 104. Referring to FIG. 2, the exposed portions of UBM layers 104 are removed by wet etching. It is observed that undercuts 112 are formed under metal bump 110 due to the lateral etching of titanium layer 106. Width W1 of undercuts 112 may be as great as 3 μm. As a result, metal bump 110 may delaminate from metal pad 102, resulting in a low yield in the metal bump formation process.

### SUMMARY

In accordance with one aspect, a method of forming a device includes forming an under-bump metallurgy (UBM) layer including a barrier layer and a seed layer over the barrier layer; and forming a mask over the UBM layer. The mask covers a first portion of the UBM layer, and a second portion of the UBM layer is exposed through an opening in the mask. The first portion of the UBM layer includes a barrier layer portion and a seed layer portion. A metal bump is formed in the opening and on the second portion of the UBM layer. The mask is then removed. A wet etch is performed to remove the seed layer portion. A dry etch is performed to remove the barrier layer portion.

Other embodiments are also disclosed.

### BRIEF DESCRIPTION OF THE DRAWINGS

For a more complete understanding of the embodiments, and the advantages thereof, reference is now made to the following descriptions taken in conjunction with the accompanying drawings, in which:

FIGS. 1 and 2 are cross-sectional views of intermediate stages in the manufacturing of a metal bump in a conventional process;

FIGS. 3 through 8 are cross-sectional views of intermediate stages in the manufacturing of a metal bump in accordance with an embodiment; and

FIGS. 9 through 12 are cross-sectional views of intermediate stages in the manufacturing of a metal pad and a redistribution line in accordance with alternative embodiments.

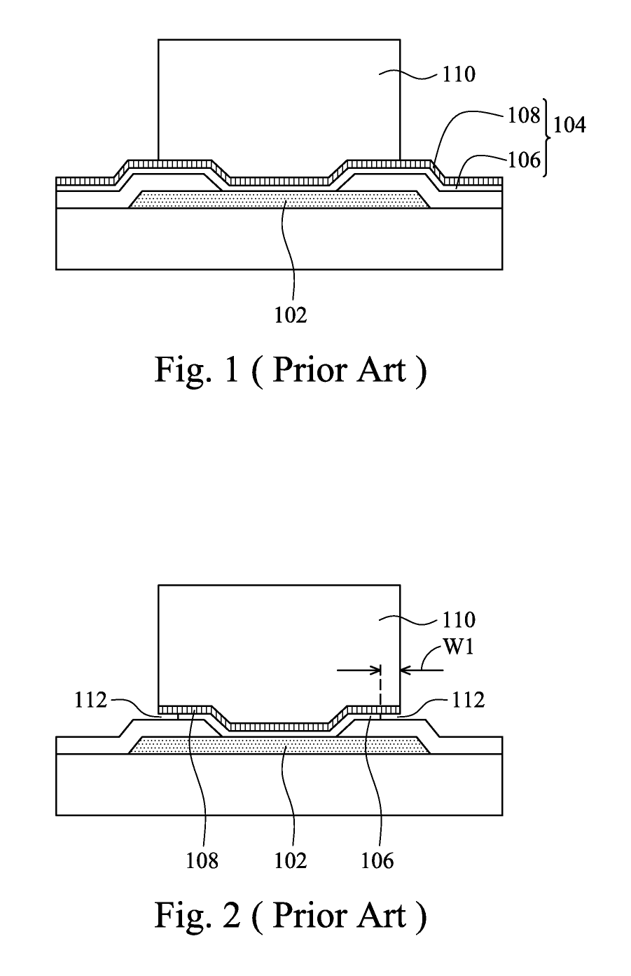

### DETAILED DESCRIPTION OF ILLUSTRATIVE EMBODIMENTS

The making and using of the embodiments of the disclosure are discussed in detail below. It should be appreciated, however, that the embodiments provide many applicable inventive concepts that can be embodied in a wide variety of specific contexts. The specific embodiments discussed are merely illustrative, and do not limit the scope of the disclosure.

A novel method for forming metal bumps with reduced undercuts in the underlying under-bump metallurgies (UBMs) is provided in accordance with an embodiment. The intermediate stages of manufacturing the embodiment are illustrated. The variations of the embodiment are discussed. Throughout the various views and illustrative embodiments, like reference numbers are used to designate like elements.

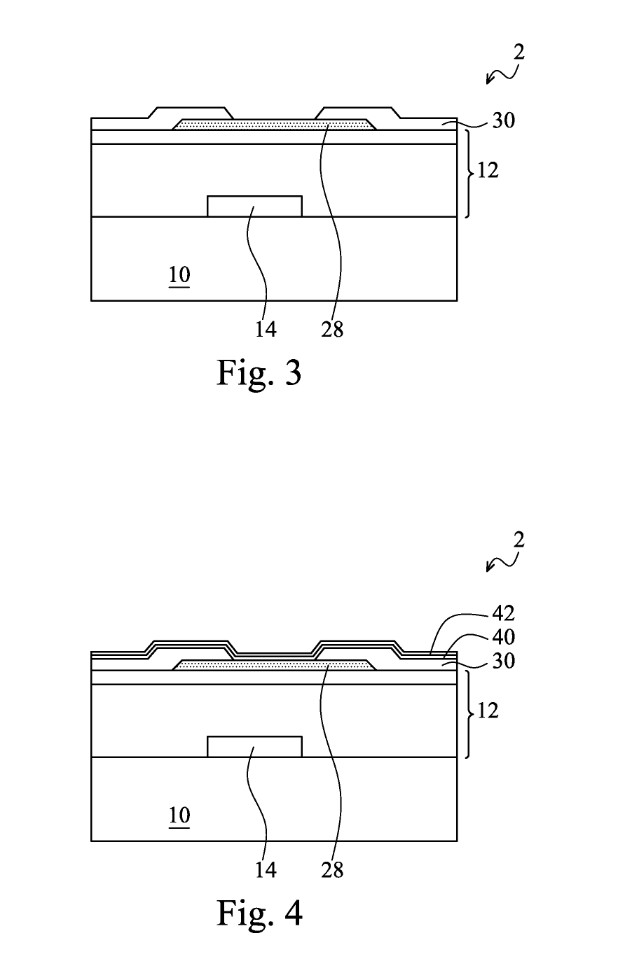

Referring to FIG. 3, wafer 2, which includes substrate 10, is provided. In an embodiment, substrate 10 is a semiconductor substrate, such as a silicon substrate, although it may include other semiconductor materials, such as silicon germanium, silicon carbide, gallium arsenide, or the like. Semiconductor devices 14, such as transistors, may be formed at the surface of substrate 10. Interconnect structure 12, which includes metal lines and vias (not shown) formed therein and electrically coupled to semiconductor devices 14, is formed over substrate 10. The metal lines and vias may be formed of copper or copper alloys, and may be formed using the well-known damascene processes. Interconnect structure 12 may include an inter-layer dielectric (ILD) and inter-metal dielectrics (IMDs). In alternative embodiments, wafer 2 is an interposer wafer or a wafer of package substrates, and is substantially free from integrated circuit devices including transistors, resistors, capacitors, inductors, and/or the like, formed therein. In these embodiments, substrate 10 may be formed of a semiconductor material or a dielectric material such as silicon oxide.

Metal pad 28 is formed over interconnect structure 12. Metal pad 28 may comprise aluminum (Al), copper (Cu), silver (Ag), gold (Au), nickel (Ni), tungsten (W), alloys thereof, and/or multi-layers thereof. Metal pad 28 may be electrically coupled to semiconductor devices 14, for example, through the underlying interconnection structure 12. Passivation layer 30 may be formed to cover edge portions of metal pad 28. In an exemplary embodiment, passivation layer 30 is formed of polyimide or other known dielectric materials such as silicon oxide, silicon nitride, and multi-layers thereof.

Referring to FIG. 4, an under-bump metallurgy (UBM), which includes barrier layer 40 and seed layer 42, is blanket formed. Barrier layer 40 extends into the opening in passivation layer 30 and contacts metal pad 28. Barrier layer 40 may be a titanium layer, a titanium nitride layer, a tantalum layer, or a tantalum nitride layer. The materials of seed layer 42 may include copper or copper alloys, and hence seed layer 42 is alternatively referred to as a copper seed layer hereinafter. However, other metals, such as silver, gold, aluminum, and combinations thereof, may also be included. In an embodiment, barrier layer 40 and seed layer 42 are formed using physical vapor deposition or other applicable methods. Barrier layer 40 may have a thickness between about 500 Å and about 2,000 Å. Seed layer 42 may have a thickness between about 1,000 Å and about 10,000 Å, although different thicknesses may be used.

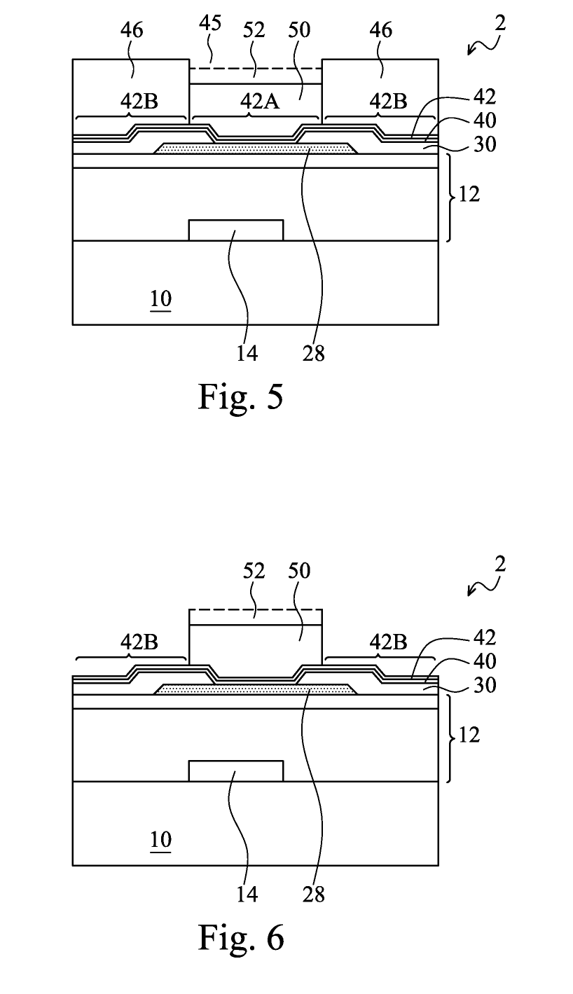

FIG. 5 illustrates the formation of mask 46, which may be formed of a photo resist or a dry film, for example. Mask 46 is patterned, and a first portion 42A of seed layer 42 is exposed through opening 45 in mask 46, while second portions 42B of seed layer 42 are covered by mask 46. Next, wafer 2 is placed into a plating solution (not shown), and a plating step is performed to form metal bump 50 on portion 42A of seed layer 42 and in opening 45. The plating may be an electro-plating, an electroless-plating, an immersion plating, or the like. In an embodiment, metal bump 50 is a copper bump. In alternative embodiments, metal bump 50 is a solder bump, which may be formed of an Sn—Ag alloy, an Sn—Ag—Cu alloy, or the like, and may be lead-free or lead-containing.

In the embodiment wherein metal bump 50 is a copper bump, additional layers 52 such as solder cap, a nickel layer, a tin layer, a palladium layer, a gold layer, alloys thereof, and/or multi-layers thereof, may be formed on the surface of metal bump 50. Further, the additional layers may be formed before or after the subsequent removal of mask 46, which removal step is shown in FIG. 6. After the formation of metal bump 50, mask 46 is removed, and the portions of UBM 40/42 previously covered by mask 46 (including copper portions 46B) are exposed. The resulting structure is shown in FIG. 6.

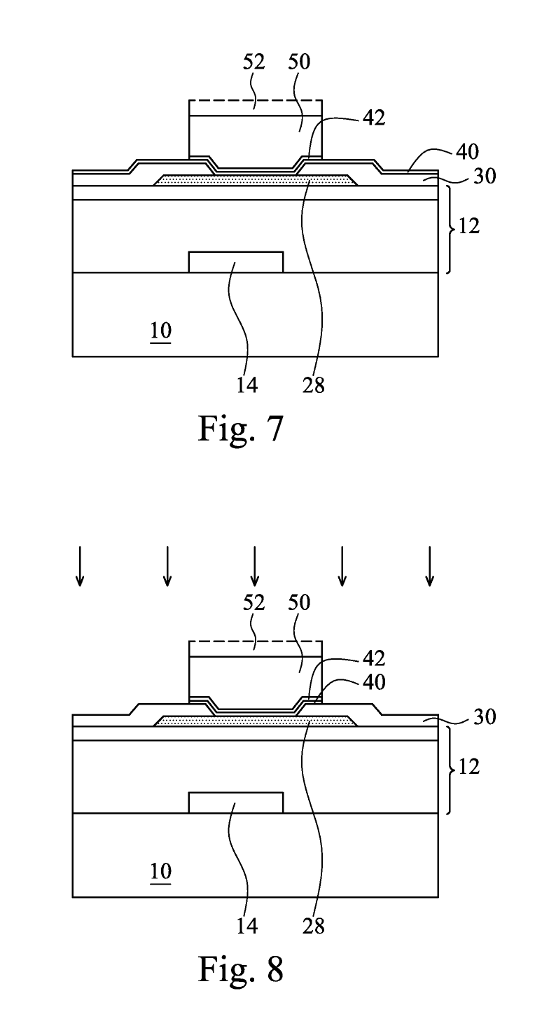

FIG. 7 illustrates the removal of portions 42B of seed layer 42 using an isotropic etching such as a wet etch. In an embodiment wherein seed layer 42 is a copper seed layer, the etchant may include copper ammonium chloride (Cu(NH₃)₄Cl₂), ammonia (NH₃), and ammonium chloride (NH₄Cl). Alternatively, the etchant may include diluted phosphoric acid (H₃PO₄) and hydrogen peroxide (H₂O₂). After the removal of seed layer 42, portions of barrier layer 40 are exposed.

Referring to FIG. 8, the exposed portions of barrier layer 40 are removed using an anisotropic etch. In an exemplary embodiment, the anisotropic etch is a dry etch with plasma (symbolized by arrows) turned on. In the embodiment wherein barrier layer 40 is a titanium layer, the etching gases may include fluorine-based gases such as CF₄ and/or CHF₃, for example. The reaction may be expressed as:

Ti+F⁻->TiF_{X} [Eq. 1]

Wherein x is an integer equal to 1, 2, etc. The resulting gas TiFₓ is removed from the reaction chamber. In alternative embodiments, the etching gases of barrier layer 40 may include chlorine-based gases such as Cl₂, or the combination of the chlorine-based gases and fluorine-based gases. The pressure of the etching gases may be about 1 mtorr to about 100 mtorr, and may be about 10 mtorr. When barrier layer 40 has a thickness of about 1,000 Å, the dry etching process may take a couple of minutes.

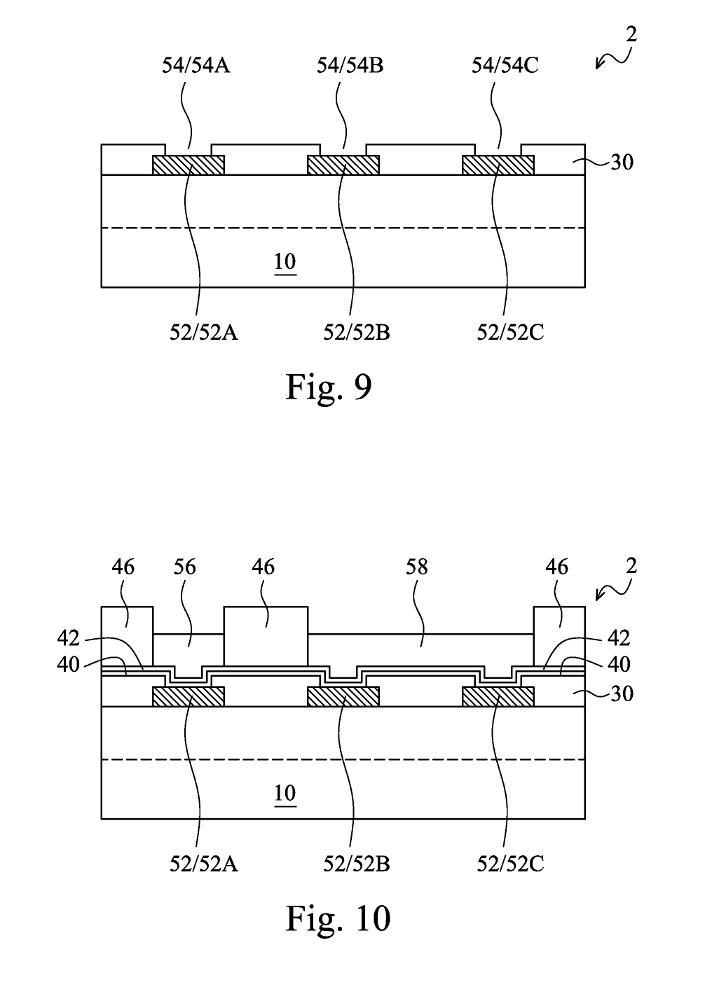

FIGS. 9 through 12 illustrate the cross-sectional views in accordance with various alternative embodiments. Unless specified otherwise, the reference numerals in these embodiments represent like elements as in the embodiments illustrated in FIGS. 3 through 8. Referring to FIG. 9, wafer 2 includes metal lines (or metal pads) 53 (including 53A, 53B, and 53C), which may be copper, aluminum, copper-aluminum, or other applicable metals. Passivation layer 30 is formed to cover metal lines 53. Next, openings 54 (including 54A, 54B, and 54C) are formed in passivation layer 30, with metal lines 53 exposed through openings 54.

Referring to FIG. 10, UBM 40/42 is blanket formed. The materials and the formation processes of UBM 40/42 are essentially the same as in the embodiments shown in FIGS. 3 through 8, wherein barrier layer 40 may be a titanium layer, and seed layer 42 may be a copper layer. UBM 40/42 extends into openings 54 to contact metal lines 53. Next, mask 46 is formed and patterned to form openings, through which UBM 40/42 is exposed. Metal pad 56 and redistribution line 58 are then formed in the openings in mask 46, for example, using plating. In an embodiment, metal pad 56 and redistribution line 58 are formed of copper or a copper alloy.

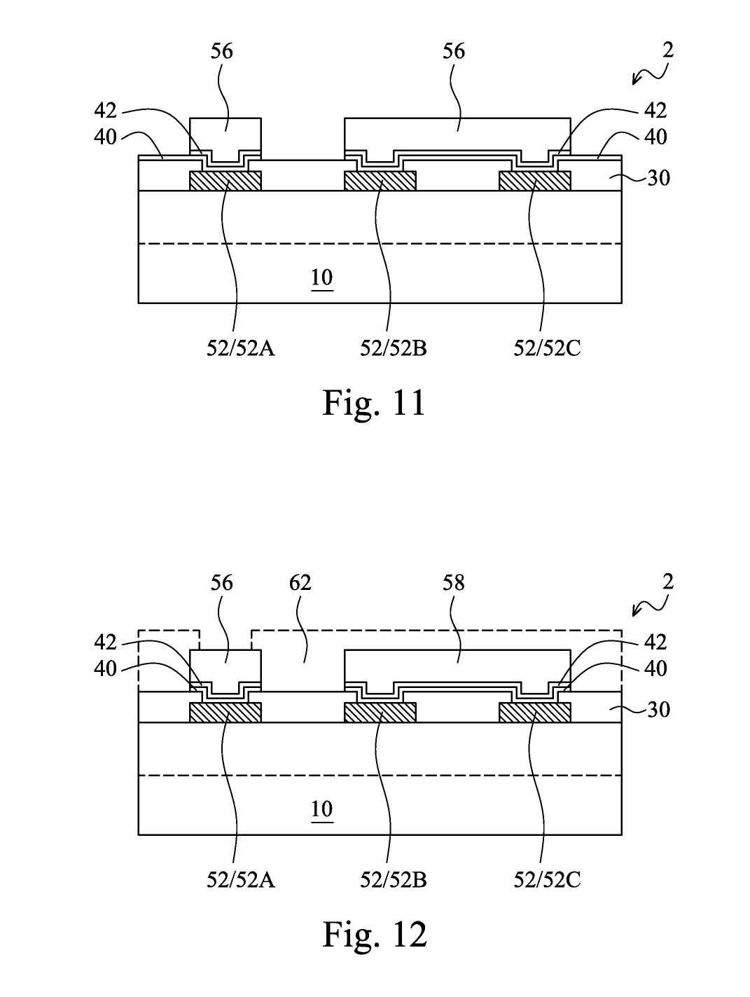

In FIG. 11, mask 46 is removed, and exposed portions of seed layer 42 are removed, for example, using an anisotropic etch such as a wet etch, next, as shown in FIG. 12, barrier layer 40 is etched using an anisotropic etch such as a plasma assisted dry etch. Further, the chlorine-based gases and/or fluorine-based gases may be used for etching barrier layer 40. The resulting structure is shown in FIG. 12.

FIG. 12 also illustrates the formation of dielectric layer 62, which may be, for example, a solder mask formed of a photo resist. Dielectric layer 62 covers redistribution line 58, while a portion of metal pad 56 is exposed. In the resulting structure, metal pad 56 may be used as a bump for bonding the respective chip in wafer 2 to another chip or to a package substrate (not shown). Redistribution line 58 is used to interconnect metal lines 53B and 53C, and is used to route electrical signals between metal lines 53B and 53C.

By using the embodiments, the undercuts to barrier layer 40 (FIGS. 8 and 12), if any, is significantly reduced to 1 μm or even less. With a well-controlled process, the undercuts were essentially eliminated in experiments. Accordingly, the reliability of the metal bump formation process and the redistribution line formation process is significantly improved due to the reduced delamination caused by the undercuts.

Although the embodiments and their advantages have been described in detail, it should be understood that various changes, substitutions and alterations can be made herein without departing from the spirit and scope of the embodiments as defined by the appended claims. Moreover, the scope of the present application is not intended to be limited to the particular embodiments of the process, machine, manufacture, and composition of matter, means, methods and steps described in the specification. As one of ordinary skill in the art will readily appreciate from the disclosure, processes, machines, manufacture, compositions of matter, means, methods, or steps, presently existing or later to be developed, that perform substantially the same function or achieve substantially the same result as the corresponding embodiments described herein may be utilized according to the disclosure. Accordingly, the appended claims are intended to include within their scope such processes, machines, manufacture, compositions of matter, means, methods, or steps. In addition, each claim constitutes a separate embodiment, and the combination of various claims and embodiments are within the scope of the disclosure.

What is claimed is:

1. A method of forming a device, the method comprising:
providing a substrate;
forming an under-bump metallurgy (UBM) layer comprising a barrier layer overlying the substrate and a seed layer overlying the barrier layer;
forming a mask overlying the UBM layer, wherein the mask covers a first portion of the UBM layer, with a second portion of the UBM layer exposed through an opening in the mask, and wherein the first portion of the UBM layer comprises a barrier layer portion and a seed layer portion;
forming a metal bump in the opening and on the second portion of the UBM layer;
removing the mask;
performing a wet etch to remove the seed layer portion; and
performing a dry etch to remove the barrier layer portion.

2. The method of claim 1, wherein the barrier layer comprises titanium, and the seed layer comprises copper.

3. The method of claim 1, wherein the dry etch is performed with plasma turned on.

4. The method of claim 1, wherein the dry etch is performed using a fluorine-based gas as an etchant gas.

5. The method of claim 4, wherein the fluorine-based gas is selected from the group consisting essentially of CF₄, CHF₃, and combinations thereof.

6. The method of claim 1, wherein the dry etch is performed using a chlorine-based gas as an etchant gas.

7. The method of claim 6, wherein the chlorine-based gas comprises Cl₂.

8. The method of claim 1, wherein the metal bump comprises a copper bump.

9. The method of claim 8, wherein the metal bump comprises a cap layer formed on the copper bump, and the cap layer comprises at least one of a nickel layer and a solder layer.

10. A method of forming a device, the method comprising:
providing a substrate;
forming a metal pad over the substrate;
forming a passivation layer over the metal pad;
forming a titanium barrier layer over the passivation layer and extending into an opening in the passivation layer to contact the metal pad;
forming a copper seed layer over the titanium barrier layer;
forming a mask over the copper seed layer, wherein the mask covers a first portion of the copper seed layer, and wherein a second portion of the copper seed layer is not covered by the mask;
performing a plating process to form a metal bump on the second portion of the copper seed layer;
removing the mask to expose the first portion of the copper seed layer;
performing a wet etch to remove the first portion of the copper seed layer to expose a portion of the titanium barrier layer; and
performing a plasma assisted dry etch to remove the portion of the titanium barrier layer.

11. The method of claim 10, wherein the plasma assisted dry etch is performed using a fluorine-based gas as an etchant gas.

12. The method of claim 11, wherein the fluorine-based gas is selected from the group consisting essentially of CF₄, CHF₃, and combinations thereof.

13. The method of claim 10, wherein the plasma assisted dry etch is performed using a chlorine-based gas as an etchant gas.

14. The method of claim 13, wherein the chlorine-based gas comprises Cl₂.

15. The method of claim 10, wherein after the step of performing the plasma assisted dry etch, an undercut of the titanium barrier layer directly underlying the metal bump has a width less than about 1 μm.

16. A method of forming a device, the method comprising:
providing a substrate;
forming a first metal line and a second metal line over the substrate;
forming a passivation layer over the first and the second metal lines;
forming a titanium barrier layer over the passivation layer and extending into openings in the passivation layer to contact the first and the second metal lines;
forming a copper seed layer overlying the titanium barrier layer;
forming a mask overlying the copper seed layer, wherein the mask covers a first portion of the copper seed layer, and wherein a second portion of the copper seed layer is not covered by the mask;
forming a redistribution line over and contacting the second portion of the copper seed layer;
removing the mask to expose the first portion of the copper seed layer;
performing a wet etch to remove the first portion of the copper seed layer and to expose a portion of the titanium barrier layer; and
performing a plasma assisted dry etch to remove the portion of the titanium barrier layer.

17. The method of claim 16, wherein the plasma assisted dry etch is performed using a fluorine-based gas as an etchant gas, and wherein the fluorine-based gas is selected from the group consisting essentially of CF₄, CHF₃, and combinations thereof.

18. The method of claim 16, wherein the plasma assisted dry etch is performed using a chlorine-based gas as an etchant gas comprising Cl₂.

19. The method of claim 16, wherein after the step of performing the plasma assisted dry etch, an undercut of the titanium barrier layer directly underlying the redistribution line has a width less than about 1 μm.

20. The method of claim 16 further comprising:
forming a metal pad simultaneously with the step of forming the redistribution line; and
forming a dielectric layer to cover the redistribution line, wherein a portion of the metal pad is not covered by the dielectric layer.
